(19) United States
(12) Patent Application Publication
(10) Pub. No.: US 2023/0171969 A1
(43) Pub. Date: Jun. 1, 2023

(54) SEMICONDUCTOR STRUCTURE AND FABRICATION METHOD THEREOF

(71) Applicants: CHANGXIN MEMORY TECHNOLOGIES, INC., Hefei (CN); Beijing Superstring Academy of Memory Technology, Beijing (CN)

(72) Inventors: Xiaoguang WANG, Hefei (CN); Huihui LI, Hefei (CN); Wei CHANG, Hefei (CN); Kanyu CAO, Hefei (CN)

(21) Appl. No.: 17/827,799

(22) Filed: May 30, 2022

Related U.S. Application Data
(63) Continuation of application No. PCT/CN2022/078090, filed on Feb. 25, 2022.

(30) Foreign Application Priority Data
Nov. 30, 2021 (CN) 202111448141.6

(51) Int. Cl. H01L 27/105

(52) U.S. Cl. CPC H01L 27/1052

(57) ABSTRACT

Embodiment provides a semiconductor structure and a fabrication method thereof, and relates to the field of semiconductor technology. The fabrication method includes providing a substrate including a peripheral circuit region and an array region having a memory cell, where the peripheral circuit region includes a first region and a second region. In the present disclosure, a logic device configured to control the memory cell and a magnetic memory device are simultaneously fabricated in the peripheral circuit region by means of a process for fabricating a dynamic random access memory (DRAM), such that the same semiconductor structure has two types of memory structures at the same time. Compared with a technology for fabricating two types of memory structures separately, fabricating steps can be simplified, and fabricating costs can be reduced.

### CROSS-REFERENCE TO RELATED APPLICATION

The present disclosure is a continuation of PCT/CN2022/078090, filed on Feb. 25, 2022, which claims priority to Chinese Patent Application No. 202111448141.6 titled “SEMICONDUCTOR STRUCTURE AND FABRICATION METHOD THEREOF” and filed to the State Intellectual Property Office on Nov. 30, 2021, the entire contents of which are incorporated herein by reference.

### TECHNICAL FIELD

The present disclosure relates to the field of semiconductor technology, and more particularly, to a semiconductor structure and a fabrication method thereof.

### BACKGROUND

As a non-volatile memory based on integration of silicon-based complementary oxide semiconductor and magnetic tunnel junction (MTJ) technology, Magnetic Random Access Memory (MRAM for short) has high-speed read and write capabilities of Static Random Access Memory (SRAM) and high integration of Dynamic Random Access Memory (DRAM).

However, due to limitations of fabrication processes, it is difficult to improve its integration when forming the MRAM, which is disadvantageous to development of semiconductor structures to the direction of integration.

### SUMMARY

A first aspect of embodiments of the present disclosure provides a method for fabricating a semiconductor structure, and the method includes following steps:
providing a substrate including a peripheral circuit region and an array region having a memory cell arranged adjacently, where the peripheral circuit region includes a first region and a second region arranged adjacently; and
forming a logic device in the first region and forming a magnetic memory device in the second region by means of a same fabrication process, the fabrication process being a process configured for fabricating a dynamic random access memory, where the logic device is connected to the memory cell to control the memory cell, and the magnetic memory device includes an access transistor and a magnetic tunnel junction connected to the access transistor.

A second aspect of the embodiments of the present disclosure provides a semiconductor structure, where the c is fabricated by the method for fabricating a semiconductor structure described in the above embodiments, and the semiconductor structure includes:
a substrate including a peripheral circuit region and an array region having a memory cell arranged adjacently, where the peripheral circuit region includes a first region and a second region arranged adjacently;
a logic device arranged in the first region and connected to the memory cell to control the memory cell; and
a magnetic memory device arranged in the second region, where the magnetic memory device includes an access transistor and a magnetic tunnel junction connected to the access transistor.

In addition to the technical problems solved by the embodiments of the present disclosure described above, technical features constituting technical solutions and beneficial effects brought by the technical features of these technical solutions, other technical problems that can be solved by the semiconductor structure and the fabrication method thereof provided by the embodiments of the present disclosure, other technical features included in the technical solutions and beneficial effects brought by these technical features will be described in further detail in some implementations.

### BRIEF DESCRIPTION OF THE DRAWINGS

To describe the technical solutions of the embodiments of the present disclosure or those of the prior art more clearly, the accompanying drawings required for describing the embodiments or the prior art will be briefly introduced below. Apparently, the accompanying drawings in the following description are merely some embodiments of the present disclosure. To those of ordinary skills in the art, other accompanying drawings may also be derived from these accompanying drawings without creative efforts.

FIG. 1 is a process flow diagram I of a method for fabricating a semiconductor structure according to an embodiment of the present disclosure;

FIG. 2 is a distribution diagram of an array region and a peripheral circuit region in the method for fabricating a semiconductor structure according to an embodiment of the present disclosure;

FIG. 3 is a schematic structural diagram of a substrate in the method for fabricating a semiconductor structure according to an embodiment of the present disclosure;

FIG. 4 is a process flow diagram II of the method for fabricating a semiconductor structure according to an embodiment of the present disclosure;

FIG. 5 is a schematic structural diagram of a logic transistor and an access transistor formed in a method for fabricating a semiconductor structure according to an embodiment of the present disclosure;

FIG. 6 is a schematic structural diagram of a first dielectric layer formed in the method for fabricating a semiconductor structure according to an embodiment of the present disclosure;

FIG. 7 is a schematic structural diagram of a plurality of first vias formed in the method for fabricating a semiconductor structure according to an embodiment of the present disclosure;

FIG. 8 is a schematic structural diagram of a plurality of conductive plugs formed in the method for fabricating a semiconductor structure according to an embodiment of the present disclosure;

FIG. 9 is a schematic structural diagram of a first conductive layer formed in the method for fabricating a semiconductor structure according to an embodiment of the present disclosure;

FIG. 10 is a schematic structural diagram of a first interconnect structure formed in a method for fabricating a semiconductor structure according to an embodiment of the present disclosure;

FIG. 11 is a schematic structural diagram of a second dielectric layer formed in the method for fabricating a semiconductor structure according to an embodiment of the present disclosure;

FIG. 12 is a schematic structural diagram of a magnetic layer formed in the method for fabricating a semiconductor structure according to an embodiment of the present disclosure;

FIG. 13 is a schematic structural diagram of a magnetic tunnel junction formed in the method for fabricating a semiconductor structure according to an embodiment of the present disclosure;

FIG. 14 is a schematic structural diagram of a third dielectric layer formed in the method for fabricating a semiconductor structure according to an embodiment of the present disclosure;

FIG. 15 is a schematic structural diagram of two first through-silicon vias and one second through-silicon via formed in the method for fabricating a semiconductor structure according to an embodiment of the present disclosure;

FIG. 16 is a schematic structural diagram of a second conductive layer formed in the method for fabricating a semiconductor structure according to an embodiment of the present disclosure; and

FIG. 17 is a schematic structural diagram of a second interconnect structure formed in the method for fabricating a semiconductor structure according to an embodiment of the present disclosure.

### DETAILED DESCRIPTION

In related technologies, due to limitations of fabrication processes, it is difficult to improve integration of a magnetic random access memory (MRAM), which is disadvantageous to development of semiconductor structures to the direction of integration. Based on the above technical problems, in the embodiments of the present disclosure, logic devices configured to control memory cells and magnetic memory devices are simultaneously fabricated in peripheral circuit regions by means of a process for fabricating a dynamic random access memory (DRAM), such that the same semiconductor structure has two types of memory structures at the same time. Compared with a technology for fabricating two types of memory structures separately, fabricating steps can be simplified, and fabricating costs can be reduced. In addition, by fabricating the magnetic memory devices by means of the process for fabricating a DRAM, integration of the magnetic memory devices can be improved, and it is convenient for the development of the semiconductor structures to the direction of integration.

To make the above objectives, features, and advantages of the embodiments of the present disclosure more apparent and lucid, the technical solutions in the embodiments of the present disclosure will be described clearly and completely below with reference to the accompanying drawings in the embodiments of the present disclosure. Apparently, the described embodiments are merely some but not all of the embodiments of the present disclosure. All other embodiments obtained by persons of ordinary skill in the art based on the embodiments of the present disclosure without creative efforts shall fall within the protection scope of the present disclosure.

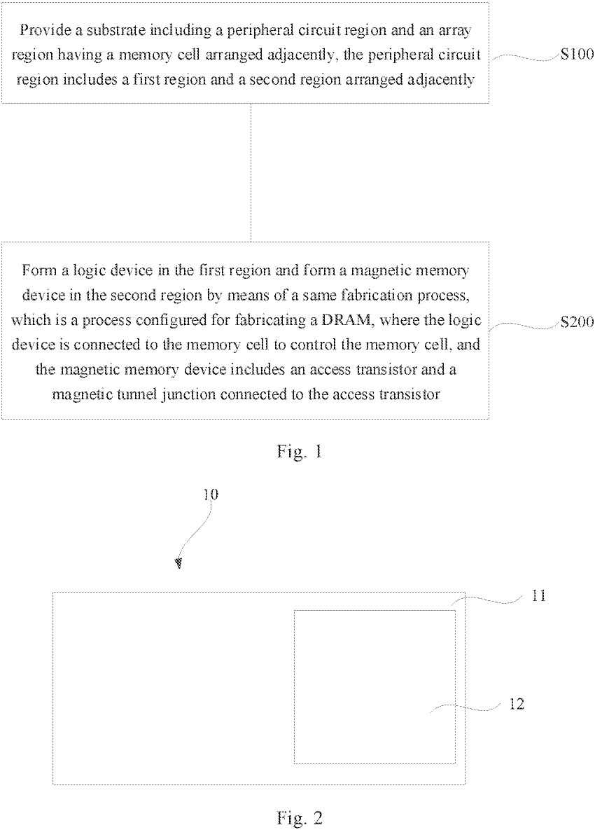

As shown in FIG. 1, a method for fabricating a semiconductor structure provided by an embodiment of the present disclosure includes following steps.

Step S100: providing a substrate including a peripheral circuit region and an array region having a memory cell arranged adjacently, where the peripheral circuit region includes a first region and a second region arranged adjacently.

Exemplarily, as shown in FIG. 2, the substrate 10 includes a peripheral circuit region 11 and an array region 12 arranged adjacently. For example, the peripheral circuit region 11 is generally arranged around the array region 12, and the array region 12 is generally configured to arrange a memory cell to implement a memory function of a memory, where the memory cell may be a device of a DRAM. That is, one memory cell includes one read transistor and one capacitor.

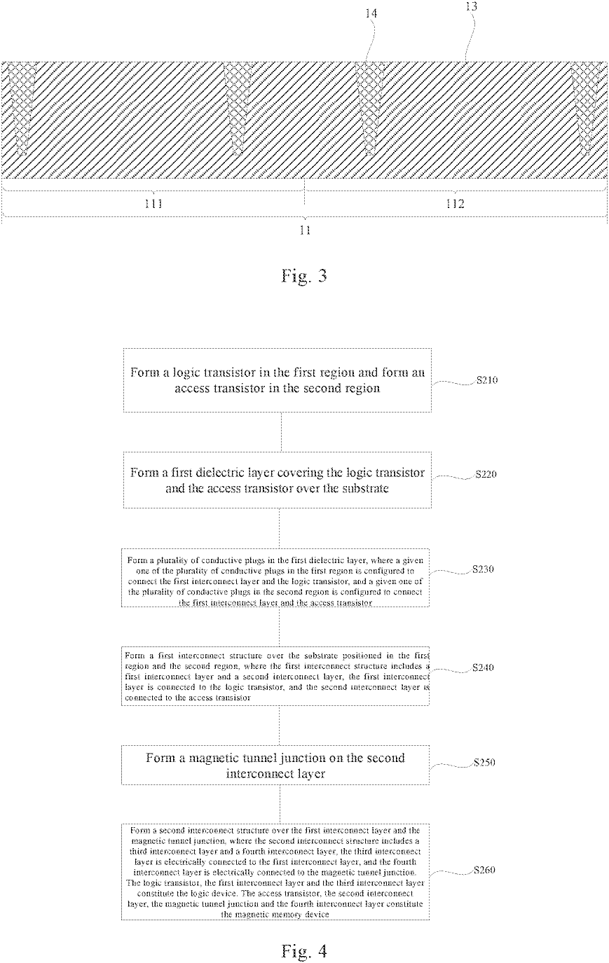

As shown in FIG. 3, a plurality of active areas 13 and isolation structures 14 configured to separate the plurality of active areas 13 are formed in the substrate 10. That is, the plurality of active areas 13 not only exist in the peripheral circuit region 11 but also exist in the array region 12.

A fabrication process of the isolation structure 14 may be as below. First, the substrate 10 is patterned to form an isolation trench in the substrate 10, and then an insulating material is deposited in the isolation trench by means of a deposition process to form the isolation structure 14, but the fabrication process of the isolation structure 14 is not limited thereto.

The substrate 10 may be made from a semiconductor material, which may be one or more of silicon, germanium, silicon-germanium compound and silicon-carbon compound. A material of the isolation structure 14 is an insulating material, which includes any one of silicon oxide, silicon nitride, silicon oxynitride and silicon carbonitride or any combination thereof.

The peripheral circuit region 11 includes a first region 111 and a second region 112 arranged adjacently, which may be understood that the first region 111 and the second region 112 are arranged side by side in a certain direction, or may also be understood that the first region 111 is arranged around the second region 112, or the second region 112 surrounds the first region 111.

Step S200: forming a logic device in the first region and forming a magnetic memory device in the second region by means of a same fabrication process, which is a process configured for fabricating a dynamic random access memory (DRAM), wherein the logic device is connected to the memory cell to control the memory cell, and the magnetic memory device includes an access transistor and a magnetic tunnel junction connected to the access transistor.

In this embodiment, the logic device configured to control the memory cell and the magnetic memory device are simultaneously fabricated in the peripheral circuit region by means of a process for fabricating a dynamic random access memory (DRAM), such that the same semiconductor structure has two types of memory structures at the same time. Compared with a technology for fabricating two types of memory structures separately, fabricating steps can be simplified, and fabricating costs can be reduced. In addition, by fabricating the magnetic memory device by means of the process for fabricating a DRAM, integration of the magnetic memory device can be improved, and it is convenient for the development of the semiconductor structure to the direction of integration.

In some embodiments, as shown in FIG. 4, the step of forming a logic device in the first region and forming a magnetic memory device in the second region by means of the same fabrication process include following steps.

Step S210: forming a logic transistor in the first region and forming an access transistor in the second region.

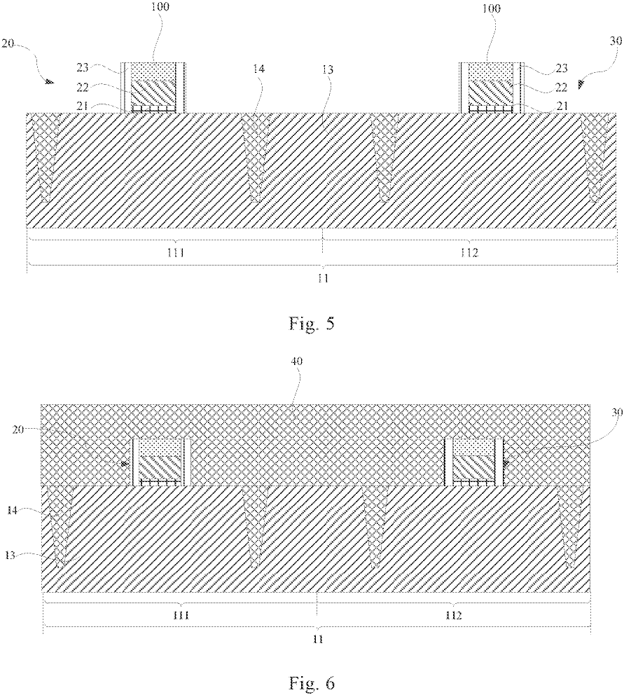

The logic transistor 20 and the access transistor 30 are formed in the same process step, and their structures are shown in FIG. 5.

Exemplarily, a channel region and a source region and a drain region respectively arranged on two sides of the channel region may be formed in a given one of the plurality of active areas 13 by means of ion implantation doping, where the source region and the drain region have the same type of doped ion, and the channel region and the source region have different types of doped ions.

Next, a gate oxide layer 21 and a gate 22 stacked are formed on the first region 111 and the second region 112 of the substrate 10, where a projection of the gate 22 on the substrate 10 covers part of the given active area 13. That is, the projection of the gate 22 on the substrate 10 at least covers the channel region, such that the gate 22 applies a voltage to the channel region.

In this step, a gate oxide material layer and a gate material layer stacked may be first formed on the substrate 10 positioned in the first region 111 and the second region 112 by means of a deposition process, where the gate oxide material layer is arranged on the substrate 10. A material of the gate oxide material layer may include silicon oxide or other materials having a high dielectric constant, such as aluminum oxide; and a material of the gate material layer may include polysilicon.

Next, a conductive material layer is formed on the gate material layer, where a material of the conductive material layer includes one or any combination of copper (Cu), tungsten (W), titanium (Ti), tantalum (Ta), cobalt (Co), titanium nitride (TiN), cobalt silicide (CoSi), and titanium aluminide (TiAl).

Finally, a mask layer is formed on the conductive material layer, then the mask layer is patterned, and then the patterned mask layer is used as a mask to sequentially etch the conductive material layer, the gate oxide material layer and the gate material layer, to form the gate oxide layer 21 and the gate 22 stacked, and to form a word line 100 on the gate 22, where the gate oxide layer 21 is positioned on an upper surface of the substrate 10.

After the gate oxide layer 21, the gate 22 and the word line 100 are formed, a protective layer 23 wrapping around a side surface of the gate 22, a side surface of the gate oxide layer 21 and a side surface of the word line 100 is formed. For example, an initial protective layer may be formed on the given active area 13 by means of a deposition process, where the initial protective layer covers the side surface of the gate oxide layer 21, the side surface of the gate 22, and the side surface and a top surface of the word line 100. Next, the initial protective layer on the top surface of the word line 100 is removed by means of an etching gas or etching liquid, and the initial protective layer retained constitutes the protective layer 23. The isolation between the gate 22 and the word line 100 and other devices may be achieved by means of the protective layer 23, where a material of the protective layer 23 may be a single-layer or multilayer insulating material comprising silicon oxide, silicon nitride or silicon oxynitride.

In this embodiment, the given active area 13, the gate oxide layer 21, the gate 22 and the protective layer 23 positioned in the first region 111 constitute the logic transistor 20. The given active area 13, the gate oxide layer 21, the gate 22 and the protective layer 23 positioned in the second region 112 constitute the access transistor 30, and the logic transistor 20 and the access transistor 30 are fabricated in the same process step, so the fabrication process can be simplified.

Step S220: forming a first dielectric layer covering the logic transistor and the access transistor over the substrate.

As shown in FIG. 6, a first dielectric layer 40 may be formed on the substrate 10 by means of a deposition process, where the first dielectric layer 40 may cover the logic transistor 20 and the access transistor 30, and a material of the first dielectric layer 40 may include an insulating material such as silicon oxide or silicon nitride.

Step S230: forming a plurality of conductive plugs in the first dielectric layer, where a given one of the plurality of conductive plugs in the first region is configured to connect the first interconnect layer and the logic transistor, and a given one of the plurality of conductive plugs in the second region is configured to connect the first interconnect layer and the access transistor.

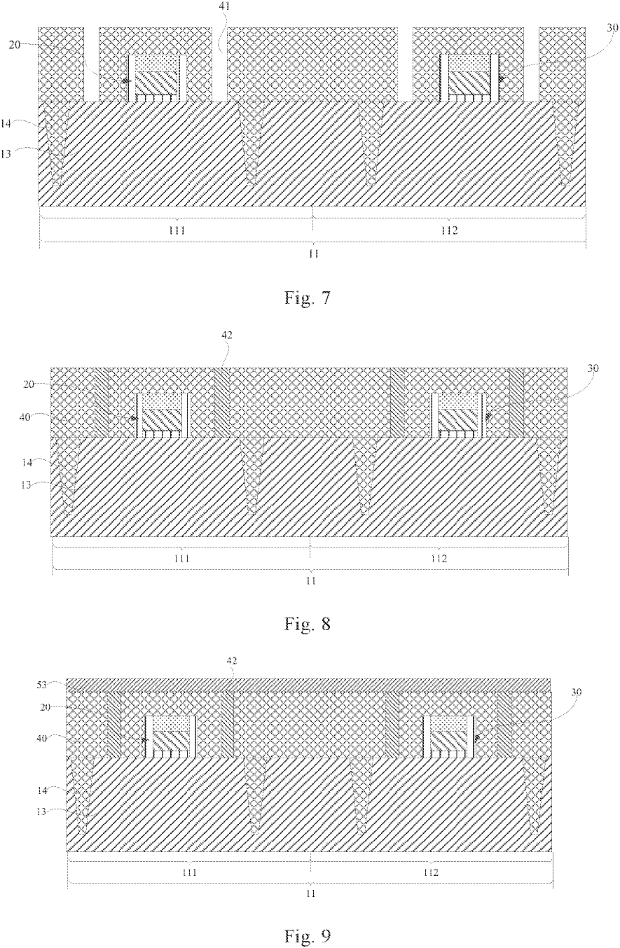

Exemplarily, as shown in FIG. 7, the first dielectric layer 40 is patterned to form a plurality of first vias 41 spaced apart in the first dielectric layer 40, and each of the plurality of first vias 41 exposes the source region or drain region of the given active areas. For example, number of the plurality of first vias 41 is four, from left to right, the first first via 41 is configured to expose the source region of the given active area 13 positioned in the first region 111, the second first via 41 is configured to expose the drain region of the given active area 13 positioned in the first region 111, and the first first via 41 and the second first via 41 are both positioned above the given active area 13; and the third first via 41 is configured to expose the source region of the given active area 13 positioned in the second region 112, the fourth first via 41 is configured to expose the drain region of the given active area 13 positioned in the second region 112, and the third first via 41 and the fourth first via 41 are both positioned above the given active area 13.

Next, as shown in FIG. 8, the conductive material is deposited on each of the plurality of first vias 41 to form the plurality of conductive plugs 42, where the plurality of conductive plugs 42 are configured to achieve connection between the plurality of active areas 13 and the first interconnect layer and the second interconnect layer formed subsequently.

Step S240: forming a first interconnect structure over the substrate positioned in the first region and the second region, where the first interconnect structure includes a first interconnect layer and a second interconnect layer, the first interconnect layer is connected to the logic transistor, and the second interconnect layer is connected to the access transistor.

Exemplarily, as shown in FIG. 9, a first conductive layer 53 is formed on the first dielectric layer 40 by means of a deposition process, where a material of the first conductive layer 53 may include one of metal tungsten, metal aluminum, metal copper, and metal titanium.

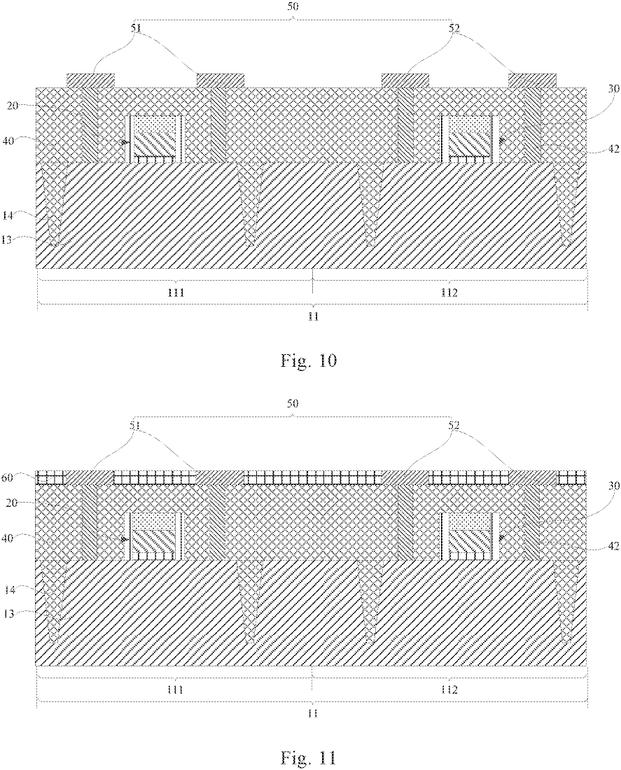

Next, as shown in FIG. 10, the first conductive layer 53 is patterned, part of the first conductive layer 53 is removed, and the first conductive layer 53 above each of the plurality of conductive plugs 42 is retained, such that the first conductive layer 53 retained constitutes the first interconnect layer 51 in the first region 111, and the first conductive layer 53 retained constitutes the second interconnect layer 52 in the second region 112, and the first interconnect layer 51 and the second interconnect layer constitute the first interconnect structure 50, where the first interconnect layer 51 and the second interconnect layer 52 are electrically connected to the plurality of conductive plugs 42, respectively.

It is to be noted that number of the first interconnect layers 51 in this embodiment is two, where one of the two first interconnect layers 51 is electrically connected to the source region of the given active area 13 positioned in the first region 111 by means of one of the plurality of conductive plug 42; and the other one of the two first interconnect layers 51 is electrically connected to the drain region of the given active area 13 positioned in the second region 112 by means of one of the plurality of conductive plug 42. Correspondingly, number of the second interconnect layer 52 is two, and the two second interconnect layer 52 are connected to the given active area 13 positioned in the second region 112 in a similar manner as the two first interconnect layer 51 are connected to the given active area 13 positioned in the first region 111.

In this embodiment, on a plane parallel to the substrate 10, a projection of the first interconnect layer 51 and a projection of the second interconnect layer 52 respectively cover projections of the plurality of conductive plugs 42 electrically connected to the first interconnect layer 51 and the second interconnect layer 52 respectively.

Taking the first first interconnect layer 51 and a given one of the plurality of conductive plugs 42 electrically connected thereto as an example for illustration, a projected area of the first interconnect layer 51 on the substrate 10 is larger than a projected area of the given conductive plug 42 on the substrate 10. Such arrangement can increase a contact area between the first interconnect layer 51 and the given conductive plug 42, reduce a contact resistance between the first interconnect layer 51 and the given conductive plug 42, and improve performance of the semiconductor structure.

As shown in FIG. 11, to achieve the insulation between the first interconnect layer 51 and the second interconnect layer 52 and the insulation between the adjacent first interconnect layers 51 or the adjacent second interconnect layers 52, a second dielectric layer 60 is provided between the first interconnect layer 51 and the second interconnect layer 52 and between the adjacent first interconnect layers 51 or the adjacent second interconnect layers 52.

Step S250: forming a magnetic tunnel junction on the second interconnect layer.

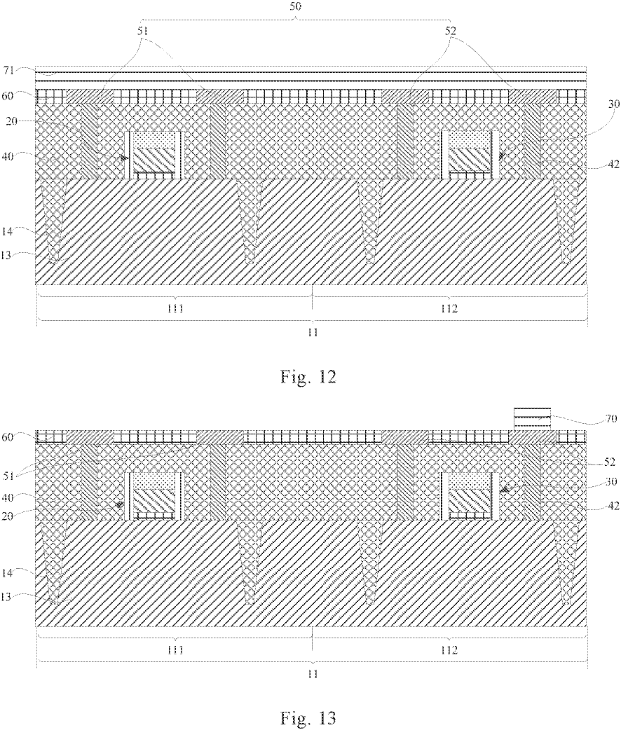

Exemplarily, as shown in FIG. 12 and FIG. 13, a magnetic layer 71 is formed on the first interconnect structure 50 and the second dielectric layer 60 by means of a deposition process, and then the magnetic layer 71 is patterned to remove part of the magnetic layer 71, the magnetic layer 71 on the second interconnect layer 52 on the second region 112 is retained, and the magnetic layer 71 retained constitutes a magnetic tunnel junction 70, where the magnetic tunnel junction 70 includes a fixed layer, a tunneling layer and a free layer stacked. When the semiconductor structure operates normally, a magnetization direction of the free layer may be changed, while a magnetization direction of the fixed layer remains unchanged. When the magnetization direction of the free layer changes with respect to the magnetization direction of the fixed layer, a resistance value of the magnetic memory device changes accordingly, and corresponds to different stored information.

It is to be noted that when the magnetic tunnel junction 70 is connected to the drain region of the access transistor 30, correspondingly, the magnetic tunnel junction 70 is formed on the given conductive plug 42 connected to the drain region. When the magnetic tunnel junction 70 is connected to the source region of the access transistor 30, correspondingly, the magnetic tunnel junction 70 is formed on the given conductive plug 42 connected to the source region.

In this embodiment, the magnetic tunnel junction 70 is formed on the second interconnect layer in the first interconnect structure by means of a fabrication process for forming a dynamic random access memory. Compared with the solution in the related technologies where the magnetic tunnel junction 70 is formed on the fourth interconnect layer, number of magnetic memory devices per unit area may be increased, such that the integration of the magnetic memory devices can improved.

Step S260: forming a second interconnect structure over the first interconnect layer and the magnetic tunnel junction, where the second interconnect structure includes a third interconnect layer and a fourth interconnect layer, the third interconnect layer is electrically connected to the first interconnect layer, and the fourth interconnect layer is electrically connected to the magnetic tunnel junction. The logic transistor, the first interconnect layer and the third interconnect layer constitute the logic device. The access transistor, the second interconnect layer, the magnetic tunnel junction and the fourth interconnect layer constitute the magnetic memory device.

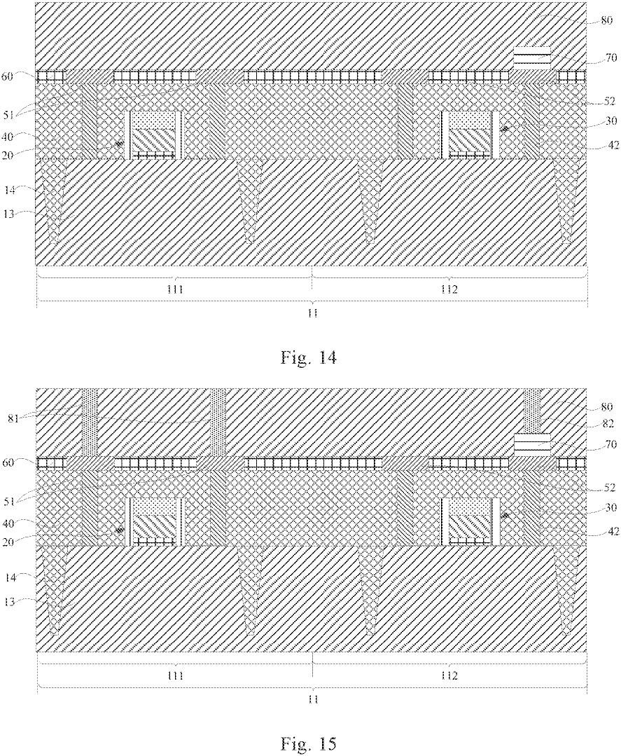

Exemplarily, as shown in FIG. 14, a third dielectric layer 80 is formed on the first interconnect structure 50 and the magnetic tunnel junction 70 by means of a deposition process. A material of the third dielectric layer 80 may include silicon oxide and silicon nitride.

As shown in FIG. 15, two first through-silicon vias 81 and one second through-silicon via 82 spaced apart are formed in the third dielectric layer 80, where the two first through-silicon vias 81 are positioned above the first region 111 and are electrically connected to the first interconnect layers 51, and the second through-silicon via 82 is positioned above the second region 112 and is electrically connected to the magnetic tunnel junction 70.

Taking an orientation shown in FIG. 15 as an example, number of the first through-silicon vias 81 is two, and the two first through-silicon vias 81 are arranged in a one-to-one correspondence with the two first interconnect layers 51.

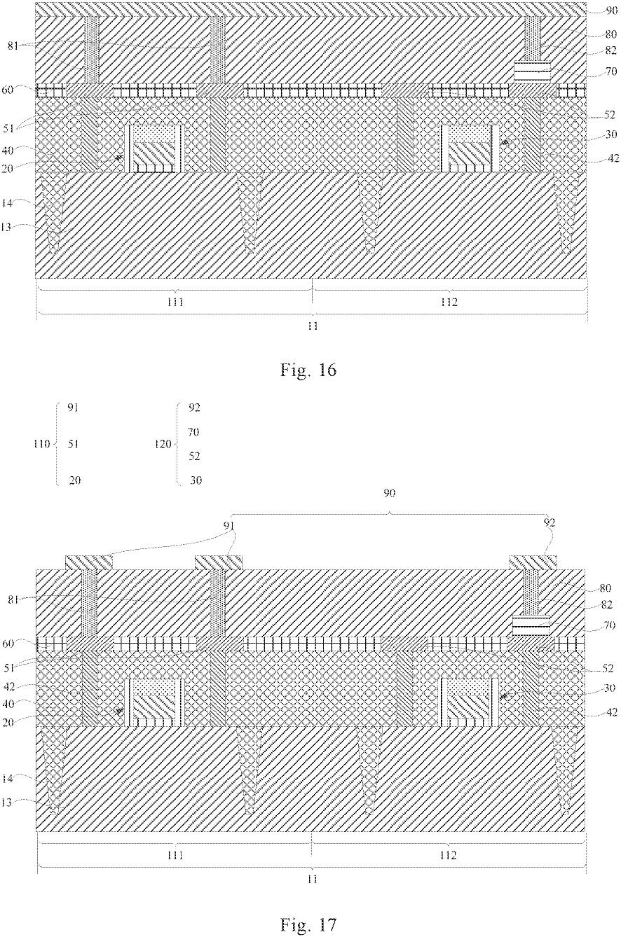

After the two first through-silicon vias 81 and the second through-silicon via 82 are formed, as shown in FIG. 16, a second conductive layer 93 is formed on the third dielectric layer 80.

As shown in FIG. 17, part of the second conductive layer 93 is removed, such that the second conductive layer 93 retained forms a third interconnect layer 91 in the first region, and the second conductive layer 93 retained forms a fourth interconnect layer 92 in the second region. The third interconnect layer 91 and the fourth interconnect layer 92 constitute the second interconnect structure 90, where the third interconnect layer 91 is electrically connected to the first through-silicon via 81, the fourth interconnect layer 92 is electrically connected to the second through-silicon via 82, and the fourth interconnect layer 92 may be used as a bit line structure of the magnetic memory device 120.

It is to be noted that number of the third interconnect layers 91 in this embodiment is two, which corresponds to the number of the first through-silicon vias 81. Taking the orientation shown in FIG. 17 as an example, from left to right, the first third interconnect layer 91 is connected to the first first interconnect layer 51 by means of the first first through-silicon via 81, and the second third interconnect layer 91 is connected to the second first interconnect layer 51 by means of the second first through-silicon via 81 to avoid crosstalk in signal transmission.

There may also be other exemplary embodiments for the formation of the third interconnect layer 91 and the fourth interconnect layer 92. For example, after the first through-silicon vias 81 and the second through-silicon via 82 are formed, an insulating layer is formed on the third dielectric layer 80, the insulating layer is patterned to form a trench, which exposes the top of the first through-silicon via 81 and the top of the second through-silicon via 82. A conductive material is deposited in the trench, where the conductive material electrically connected to the first through-silicon via 81 constitutes the third interconnect layer 91, and the conductive material electrically connected to the second through-silicon via 82 constitutes the fourth interconnect layer 92. The insulating layer is positioned between the third interconnect layer 91 and the fourth interconnect layer 92, and is configured to isolate the third interconnect layer 91 from the fourth interconnect layer 92, to play a role of insulation.

In this embodiment, the logic transistor 20, the first interconnect layer 51 and the third interconnect layer 91 constitute the logic device 110; and the access transistor 30, the second interconnect layer 52, the magnetic tunnel junction 70 and the fourth interconnect layer 92 constitute the magnetic memory device 120.

In this embodiment, the logic device configured to control the memory cell and the magnetic memory device are simultaneously fabricated in the peripheral circuit region by means of the process for fabricating a dynamic random access memory (DRAM), such that the same semiconductor structure has two types of memory structures at the same time. Compared with the technology for fabricating two types of memory structures separately, fabricating steps can be simplified, and fabricating costs can be reduced. In addition, by fabricating the magnetic memory device by means of the process for fabricating a DRAM, integration of the magnetic memory device can be improved, and it is convenient for the development of the semiconductor structure to the direction of integration.

The embodiments of the present disclosure also provide a semiconductor structure, which is fabricated by the method for fabricating a semiconductor structure in the above-mentioned embodiments.

As shown in FIG. 17, the semiconductor structure includes a substrate 10, a logic device 110, and a magnetic memory device 120. The substrate 10 includes a peripheral circuit region 11 and an array region 12 having a memory cell arranged adjacently, and the peripheral circuit region 11 includes a first region 111 and a second region 112 arranged adjacently, where an area of the first region 111 may be the same as or may be different from that of the second region 112.

The logic device 110 is arranged in the first region 111 and is connected to the memory cell arranged in the array region 12 to control the memory cell.

The magnetic memory device 120 is arranged in the second region 112, where the magnetic memory device 120 includes an access transistor 30 and a magnetic tunnel junction 70 connected to the access transistor 30.

In this embodiment, the semiconductor structure not only has the memory cell of the dynamic random access memory, but also has the magnetic tunnel junction of the magnetic random access memory, such that the same semiconductor structure has two different types of memory devices, which can improve diversity of the semiconductor structure.

In some embodiments, the logic device 110 includes a logic transistor 20, a first interconnect layer 51 and a third interconnect layer 91, where the first interconnect layer 51 and the third interconnect layer 91 are stacked on the logic transistor 20. The first interconnect layer 51 is connected to the logic transistor 20 by means of a given conductive plug 42 positioned above the first region 111. For example, the first first interconnect layer 51 is connected to a source region of the logic transistor 20 by means of a first conductive plug 42 positioned above the first region 111, and the second first interconnect layer 51 is connected to a drain region of the logic transistor 20 by means of a second conductive plug 42 positioned above the first region 111.

The third interconnect layer 91 is connected to the first interconnect layer 51 by means of the first through-silicon via 81 to achieve transmission of electrical signals between the first interconnect layer 51 and the third interconnect layer 91, where a material of the first through-silicon via 81 may include copper.

In some embodiments, the magnetic memory device 120 also includes a second interconnect layer 52 and a fourth interconnect layer 92, where the second interconnect layer 52 is arranged between the access transistor 30 and the magnetic tunnel junction 70 to allow the access transistor 30 is electrically connected to the magnetic tunnel junction 70. That is, an upper surface of the second interconnect layer 52 is connected to the magnetic tunnel junction 70, and a lower surface of the second interconnect layer 52 is electrically connected to the access transistor 30.

The lower surface of the second interconnect layer 52 may be directly connected or may be indirectly connected to the access transistor 30. For example, the second interconnect layer 52 and the access transistor are connected by means of the given conductive plug 42 positioned on the second region 112.

The fourth interconnect layer 92 is arranged on the magnetic tunnel junction 70 and is electrically connected to the magnetic tunnel junction 70. For example, the fourth interconnect layer 92 is connected to the magnetic tunnel junction 70 by means of the second through-silicon via 82. In this embodiment, electrical connection between various components in the magnetic memory device is achieved by means of the second through-silicon via 82 and the plurality of conductive plugs positioned on the second region 112.

The embodiments or the implementations in the specification are described in a progressive manner. Each of the embodiments is focused on difference from other embodiments, and cross reference is available for identical or similar parts among different embodiments.

In the descriptions of this specification, descriptions of reference terms “one embodiment”, “some embodiments”, “an exemplary embodiment”, “an example”, “one example”, or “some examples” are intended to indicate that features, structures, materials, or characteristics described with reference to the embodiment or example are included in at least one embodiment or example of the present disclosure.

The schematic representation of the above terms throughout this specification does not necessarily refer to the same embodiment or example. Furthermore, the features, structures, materials, or characteristics set forth may be combined in any suitable manner in one or more embodiments or examples.

Finally, it should be noted that the foregoing embodiments are merely intended for describing the technical solutions of the present disclosure, but not for limiting the present disclosure. Although the present disclosure is described in detail with reference to the foregoing embodiments, persons of ordinary skill in the art should understand that they may still make modifications to the technical solutions described in the foregoing embodiments or make equivalent replacements to some or all technical features thereof, which does not make corresponding technical solutions in essence depart from the scope of the technical solutions of the embodiments of the present disclosure.

What is claimed is:

1. A method for fabricating a semiconductor structure comprising:
providing a substrate comprising a peripheral circuit region and an array region having a memory cell arranged adjacently, the peripheral circuit region comprising a first region and a second region arranged adjacently; and
forming a logic device in the first region and forming a magnetic memory device in the second region by means of a same fabrication process, the fabrication process being a process configured for fabricating a dynamic random access memory, wherein the logic device is connected to the memory cell to control the memory cell, the magnetic memory device comprising an access transistor and a magnetic tunnel junction connected to the access transistor.

2. The method for fabricating a semiconductor structure according to claim 1, wherein the forming a logic device in the first region and forming a magnetic memory device in the second region by means of a same fabrication process comprise:
forming a logic transistor in the first region and forming an access transistor in the second region;
forming a first interconnect structure over the substrate positioned in the first region and the second region, the first interconnect structure comprising a first interconnect layer and a second interconnect layer, the first interconnect layer being connected to the logic transistor, and the second interconnect layer being connected to the access transistor;
forming the magnetic tunnel junction on the second interconnect layer; and
forming a second interconnect structure over the first interconnect layer and the magnetic tunnel junction, the second interconnect structure comprising a third interconnect layer and a fourth interconnect layer, the third interconnect layer being electrically connected to the first interconnect layer, the fourth interconnect layer being electrically connected to the magnetic tunnel junction, wherein the logic transistor, the first interconnect layer and the third interconnect layer constitute the logic device, the access transistor, the second interconnect layer, the magnetic tunnel junction and the fourth interconnect layer constituting the magnetic memory device.

3. The method for fabricating a semiconductor structure according to claim 2, wherein, the providing a substrate comprises:
forming a plurality of active areas and isolation structures configured to separate the plurality of active areas in the substrate;
the forming a logic transistor in the first region and forming an access transistor in the second region comprise:
forming a gate oxide layer and a gate stacked on the first region and the second region of the substrate, a projection of the gate on the substrate covering part of the plurality of active areas; and
forming a protective layer wrapping around a side surface of the gate and a side surface of the gate oxide layer, wherein a given one of the plurality of active areas, the gate oxide layer, the gate and the protective layer positioned in the first region constitute the logic transistor, a given one of the plurality of active areas, the gate oxide layer, the gate and the protective layer positioned in the second region constituting the access transistor.

4. The method for fabricating a semiconductor structure according to claim 3, wherein after the forming a logic transistor in the substrate in the first region and forming an access transistor in the second region and before the forming a first interconnect structure over the substrate positioned in the first region and the second region, the fabrication method further comprises:
forming a first dielectric layer covering the logic transistor and the access transistor over the substrate; and
forming a plurality of conductive plugs in the first dielectric layer, a given one of the plurality of conductive plugs in the first region being configured to connect the first interconnect layer and the logic transistor, and a given one of the plurality of conductive plugs in the second region being configured to connect the first interconnect layer and the access transistor.

5. The method for fabricating a semiconductor structure according to claim 4, wherein the forming a plurality of conductive plugs in the first dielectric layer comprises:
patterning the first dielectric layer to form a plurality of first vias spaced apart in the first dielectric layer, each of the plurality of first vias exposing a source region or drain region of the given active area; and
depositing a conductive material in each of the plurality of first vias to form the plurality of conductive plugs.

6. The method for fabricating a semiconductor structure according to claim 4, wherein the forming a first interconnect structure over the substrate positioned in the first region and the second region comprises:
forming a first conductive layer on the first dielectric layer; and
removing part of the first conductive layer, such that the first conductive layer retained constitutes the first interconnect layer in the first region, and the first conductive layer retained constitutes the second interconnect layer in the second region, wherein the first interconnect layer and the second interconnect layer are electrically connected to the plurality of conductive plugs, respectively.

7. The method for fabricating a semiconductor structure according to claim 6, wherein on a plane parallel to the substrate, a projection of the first interconnect layer and a projection of the second interconnect layer respectively cover projections of the plurality of conductive plugs electrically connected to the first interconnect layer and the second interconnect layer respectively.

8. The method for fabricating a semiconductor structure according to claim 6, wherein the forming the magnetic tunnel junction on the second interconnect layer comprises:
forming a magnetic layer on the first interconnect structure; and
removing part of the magnetic layer to retain a magnetic layer on one of the second interconnect layers above the second region, the magnetic layer retained constituting the magnetic tunnel junction.

9. The method for fabricating a semiconductor structure according to claim 7, wherein after the forming the magnetic tunnel junction on the second interconnect layer and before the forming a second interconnect structure over the first interconnect layer and the magnetic tunnel junction, the fabrication method further comprises:
forming a third dielectric layer on the first interconnect structure and the magnetic tunnel junction; and
forming a first through-silicon via and a second through-silicon via spaced apart in the third dielectric layer, the first through-silicon via being positioned above the first region and being electrically connected to one of the first interconnect layers, and the second through-silicon via being positioned above the second region and being electrically connected to the magnetic tunnel junction.

10. The method for fabricating a semiconductor structure according to claim 9, wherein the forming a second interconnect structure over the first interconnect layer and the magnetic tunnel junction comprises:
forming a second conductive layer on the third dielectric layer; and
removing part of the second conductive layer, such that the second conductive layer retained forms a third interconnect layer in the first region, and the second conductive layer retained forms a fourth interconnect layer in the second region.

11. The method for fabricating a semiconductor structure according to claim 3, wherein the forming a gate oxide layer and a gate stacked on the first region and the second region of the substrate comprises:
forming a gate oxide material layer and a gate material layer stacked on the first region and the second region of the substrate;
forming a conductive material layer on the gate material layer; and
patterning the conductive material layer, the gate oxide material layer and the gate material layer to form the gate oxide layer and the gate stacked, and to form a word line on the gate.

12. A semiconductor structure fabricated by a method, the method comprises:
providing a substrate comprising a peripheral circuit region and an array region having a memory cell arranged adjacently, the peripheral circuit region comprising a first region and a second region arranged adjacently; and
forming a logic device in the first region and forming a magnetic memory device in the second region by means of a same fabrication process, the fabrication process being a process configured for fabricating a dynamic random access memory, wherein the logic device is connected to the memory cell to control the memory cell, the magnetic memory device comprising an access transistor and a magnetic tunnel junction connected to the access transistor;
wherein the semiconductor structure comprises:
a substrate comprising a peripheral circuit region and an array region having a memory cell arranged adjacently, the peripheral circuit region comprising a first region and a second region arranged adjacently;
a logic device arranged in the first region and connected to the memory cell to control the memory cell; and
a magnetic memory device arranged in the second region, wherein the magnetic memory device comprises an access transistor and a magnetic tunnel junction connected to the access transistor.

13. The semiconductor structure according to claim 12, wherein the logic device comprises a logic transistor, a first interconnect layer and a third interconnect layer, the first interconnect layer and the third interconnect layer being stacked on the logic transistor; and
the first interconnect layer is connected to the logic transistor by means of the given conductive plug over the first region, the third interconnect layer being connected to the first interconnect layer by means of the first through-silicon via.

14. The semiconductor structure according to claim 13, wherein the magnetic memory device further comprises a second interconnect layer and a fourth interconnect layer, the second interconnect layer being arranged between the access transistor and the magnetic tunnel junction, such that the access transistor is electrically connected to the magnetic tunnel junction; and
the fourth interconnect layer is arranged on the magnetic tunnel junction and is electrically connected to the magnetic tunnel junction.

15. The semiconductor structure according to claim 14, wherein the second interconnect layer is connected to the access transistor by means of the given conductive plug on the second region, the fourth interconnect layer being connected to the magnetic tunnel junction by means of the second through-silicon via.
